(19) United States
(12) Patent Application Publication
(10) Pub. No.: US 2025/0259666 A1
(43) Pub. Date: Aug. 14, 2025

(54) MEMORY DEVICE USING DATA STROBE SIGNAL AND METHOD OF CALIBRATING DELAY THEREOF

(71) Applicant: SAMSUNG ELECTRONICS CO., LTD., Suwon-si (KR)

(72) Inventors: Tongsung Kim, Suwon-si (KR); Soohwan Yoo, Suwon-si (KR); Byungkwan Chun, Suwon-si (KR)

(21) Appl. No.: 19/051,865

(22) Filed: Feb. 12, 2025

(30) Foreign Application Priority Data
Feb. 13, 2024 (KR) 10-2024-0020668
May 10, 2024 (KR) 10-2024-0061976

(51) Int. Cl. G11C 11/4076; G11C 5/14; G11C 11/4096

(52) U.S. Cl. CPC G11C 11/4076; G11C 5/146; G11C 11/4096; G11C 2207/2254

(57) ABSTRACT

A memory device includes: a memory cell array; an input/output circuit transmitting data read from the memory cell array; control logic circuitry configured to generate a data strobe signal corresponding to the data; a clock distribution circuit including a main power insensitive circuit configured to be driven by an external supply power voltage and to transmit the data strobe signal passing through the main power insensitive circuit to the input/output circuit; a data strobe signal oscillator driven by the external supply power voltage and including a first replica power insensitive circuit; and a delay calibration circuit generating a bias voltage by comparing a first delay signal output from the data strobe signal oscillator and a second delay signal output from a second replica power insensitive circuit that is driven by an internal power voltage.

### CROSS-REFERENCE TO RELATED APPLICATIONS

This application claims priority to Korean Patent Application No. 10-2024-0020668, filed on Feb. 13, 2024, and Korean Patent Application No. 10-2024-0061976, filed on May 10, 2024, in the Korean Intellectual Property Office, the disclosures of which are incorporated by reference herein in their entireties.

### BACKGROUND

A semiconductor memory may be mainly classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off. Therefore, the non-volatile memory may be used to store contents which must be preserved regardless of whether power is supplied or not.

The semiconductor memory may exchange data under a control of a memory controller. The semiconductor memory may use a data signal (DQ) and a data strobe signal (DQS) for data exchange. During a read operation, the DQS may be output to the memory controller through a plurality of clock trees. However, when the plurality of clock trees is driven by external supply power received from the memory controller, a delay of the plurality of clock trees may change depending on a voltage change of the external supply power, and accurate data may not be transmitted to the memory controller.

### SUMMARY

In general, in some aspects, the present disclosure is directed toward a memory device and a delay calibration method that consistently maintain a delay of a data strobe signal regardless of a voltage change of external supply power received from the memory controller.

According to some implementations, the present disclosure is directed to a memory device that includes: a memory cell array including a plurality of memory cells; an input/output circuit transmitting data read from the memory cell array to a memory controller; control logic generating a data strobe signal, corresponding to the data, transmitted to the memory controller; a clock distribution circuit including a main power insensitive unit which has a specified delay and is driven by an external supply power voltage supplied from the memory controller, and transmitting the data strobe signal passing through the main power insensitive unit to the input/output circuit; a data strobe signal oscillator driven by the external supply power voltage and including a first replica power insensitive unit which has the specified delay; and a delay calibration circuit generating a bias voltage in a direction in which a phase difference between a first delay signal and a second delay signal decreases by comparing the first delay signal output from the data strobe signal oscillator and the second delay signal output from a second replica power insensitive unit which has the specified delay and is driven by an internal power voltage different from the external supply power. The clock distribution circuit adjusts a delay of the main power insensitive unit based on the bias voltage.

According to some implementations, the present disclosure is directed to a delay calibration method of a memory device that includes control logic which generates a data strobe signal, a main power insensitive unit which is driven by an external supply power voltage and transmits the data strobe signal according to a specified delay, a first replica power insensitive unit which is driven by the external supply power voltage and has the specified delay, and a second replica power insensitive unit which is driven by an internal power supply voltage generated by the control logic and has the specified delay, the method includes: receiving a data strobe signal oscillation command from a memory controller; providing the internal power voltage to the second replica power insensitive unit in response to receiving the data strobe signal oscillation command; performing a data strobe signal oscillation operation in response to the data strobe signal oscillation command; performing a delay calibrating operation by the first replica power insensitive unit and the second replica power insensitive unit while the data strobe signal oscillation operation is performed; and blocking supply of the internal power voltage to the second replica power insensitive unit when the data strobe signal oscillation operation ends.

According to some implementations, the present disclosure is directed to a delay calibration method of a memory device that includes control logic which generates a data strobe signal, a main power insensitive unit which is driven by an external supply power voltage and transmits the data strobe signal according to a specified delay, and a first replica power insensitive unit which is driven by the external supply power voltage and has the specified delay, and a second replica power insensitive unit which is driven by an internal power supply voltage generated by the control logic and has the specified delay, the method includes: receiving a duty cycle correction command from a memory controller; providing the internal power supply voltage to the second replica power insensitive unit in response to receiving the duty cycle correction command; performing a duty cycle correction in response to the duty cycle correction command; performing a delay calibrating operation by the first replica power insensitive unit and the second replica power insensitive unit while the duty cycle correction is performed; and blocking supply of the internal power voltage to the second replica power insensitive unit when the duty cycle correction ends.

### BRIEF DESCRIPTION OF THE DRAWINGS

Example implementations will be more clearly understood from the following description, taken in conjunction with the accompanying drawings.

FIG. 1 is a block diagram illustrating an example of a memory system according to some implementations.

FIG. 2 is a block diagram illustrating an example of a read operation of the memory device of FIG. 1 according to some implementations.

FIG. 3 is a graph illustrating an example of a change in delay value of the power insensitive unit of FIG. 2 according to external supply power variations according to some implementations.

FIG. 4 is a diagram illustrating an example of one inverter included in the CMOS driver of FIG. 2 according to some implementations.

FIG. 5 is a diagram illustrating an example of the bias generator of FIG. 2 according to some implementations.

FIG. 6 is a block diagram illustrating examples of a DQS oscillator and a delay calibration circuit according to some implementations.

FIG. 7 is a diagram illustrating an example of the bias generator of FIG. 6 according to some implementations.

FIG. 8 is a flowchart illustrating an example of a delay calibrating operation performed through the DQS oscillator and the delay calibration circuit of FIG. 6 according to some implementations.

FIG. 9 is a flowchart illustrating an example of a delay calibrating operation performed together with a DQS oscillation of the memory device of FIG. 2 according to some implementations.

FIG. 10 is a graph illustrating an example of an effect of the delay calibrating operation of FIG. 8 according to some implementations.

FIG. 11 is a block diagram illustrating examples of a DQS oscillator and a delay calibration circuit according to some implementations.

FIG. 12 is a flowchart illustrating an example of a delay calibrating operation performed simultaneously with a duty cycle correction of the memory device of FIG. 2 according to some implementations.

FIG. 13 is a flowchart illustrating an example of a delay calibrating operation performed through the DQS oscillator and the delay calibration circuit of FIG. 6 according to some implementations.

FIG. 14 is a graph illustrating an example of an effect of the delay calibrating operation of FIG. 13 according to some implementations.

### DETAILED DESCRIPTION

Hereinafter, example implementations will be explained in detail with reference to the accompanying drawings.

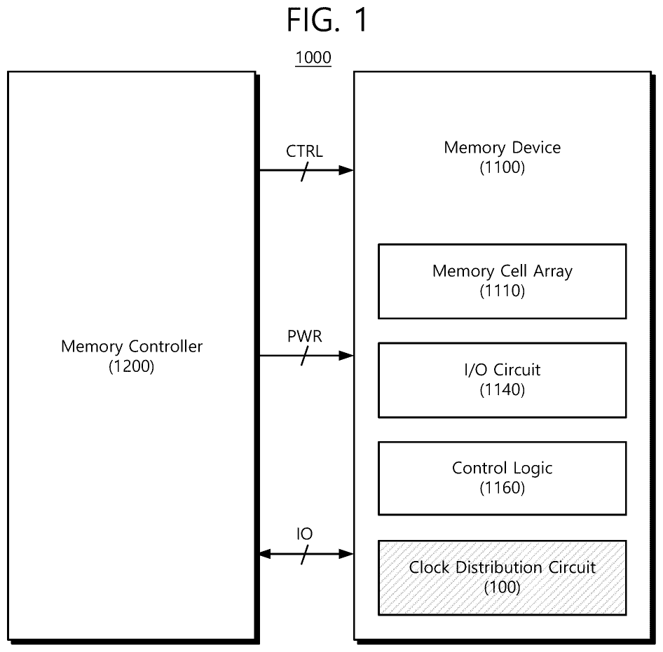

FIG. 1 is a block diagram illustrating an example of a memory system according to some implementations. In FIG. 1, a memory system 1000 may include a memory device 1100 and a memory controller 1200.

According to some implementations, the memory device 1100 may receive control signals CTRL from the memory controller 1200 through control lines, receive external supply power PWR through power lines, and transmit and receive input/output signals IO through input/output lines. The memory system 1000 may input or output data to or from the memory device 1100 through control of the memory controller 1200.

According to some implementations, the memory device 1100 may output data requested to be read by the memory controller 1200 to the memory controller 1200 or store data requested to be written by the memory controller 1200 in memory cells. The memory device 1100 may input and output data based on commands and addresses.

The memory device 1100 may be a volatile memory device, such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. In some implementations, the memory device 1100 may be implemented as a nonvolatile memory device, such as a resistive RAM (RRAM), a phase change memory (PRAM), a magnetoresistive memory (MRAM), a ferroelectric memory (FRAM), a spin-transfer torque RAM (STT-RAM), or the like.

According to some implementations, the memory device 1100 may include a memory cell array 1110. For example, the memory cell array 1110 may include a plurality of memory cells. The plurality of memory cells may have a matrix structure connected to a plurality of wordlines and a plurality of bitlines.

According to some implementations, the memory device 1100 may include an input/output circuit 1140. For example, the input/output circuit 1140 may be connected to the memory controller 1200 through input/output lines. The input/output circuit 1140 may transfer data input from the memory controller 1200 to the memory cell array 1110 during a write operation. The input/output circuit 1140 may provide data read from the memory cell array 1110 to the memory controller 1200 during a read operation.

According to some implementations, the memory device 1100 may include control logic 1160. For example, the control logic 1160 may include all analog circuits or digital circuits necessary to store data in the memory cell array 1110 or read data stored in the memory cell array 1110. The control logic 1160 may receive external supply power PWR input through power lines and generate various levels of internal powers. The control logic 1160 may generate various internal control signals based on control signals CTRL.

According to some implementations, the memory device 1100 may include a clock distribution circuit 100. For example, the clock distribution circuit 100 may transfer a clock signal received from the memory controller 1200. For example, the control signals CTRL received from the memory controller 1200 may include the clock signal. The clock distribution circuit 100 may amplify and/or propagate the received clock signal and transmit the clock signal to the input/output circuit 1140.

According to some implementations, the memory controller 1200 may perform an access operation of writing data to the memory device 1100 or reading data stored in the memory device 1100. For example, the memory controller 1200 may generate commands and addresses for writing data to the memory device 1100 or reading data stored in the memory device 1100. The memory controller 1200 may generate the control signals CTRL for the memory device 1100.

The memory controller 1200 may be at least one of a system-on-chip (SoC) such as an application processor (AP) for controlling the memory device 1100, a central processing unit (CPU), a digital signal processor (DSP) and/or a graphics processing unit (GPU).

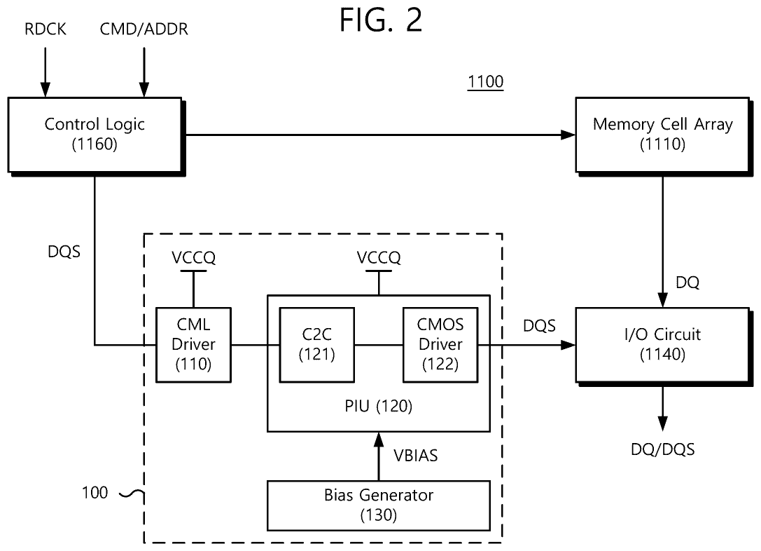

FIG. 2 is a block diagram illustrating an example of a read operation of the memory device of FIG. 1 according to some implementations. In FIGS. 1 and 2, the memory device 1100 may receive a command CMD and an address ADDR from the memory controller 1200 to perform a read operation. During the read operation, the memory device 1100 may receive a read clock signal RDCK from the memory controller 1200. The memory device 1100 may output data from the memory cell array 1110 based on the read clock signal RDCK.

According to some implementations, the control logic 1160 may receive the read clock signal RDCK and generate a data strobe signal DQS. The clock distribution circuit 100 may amplify and/or propagate the data strobe signal DQS and transmit the data strobe signal DQS to the input/output circuit 1140. When receiving the command CMD, the control logic 1160 may control the memory cell array 1110 based on the address ADDR. The memory cell array 1110 may output a data signal DQ to the input/output circuit 1140 based on the address ADDR.

According to some implementations, the input/output circuit 1140 may transmit the data signal DQ and the data strobe signal DQS to the memory controller 1200. The memory controller 1200 may obtain data from the data signal DQ based on the data strobe signal DQS. The data strobe signal DQS may be transmitted through the clock distribution circuit 100 and pass through a delay path different from the data signal DQ.

According to some implementations, the clock distribution circuit 100 may include a current mode logic (CML) driver 110, a power insensitive unit (circuit) 120, and/or a bias generator 130. The power insensitive unit 120 may include a current mode logic-complementary metal oxide semiconductor (CML-CMOS) converter 121 and/or a CMOS driver 122. The CML driver 110 may swing the data strobe signal DQS at a CML level. The CML-CMOS converter 121 may convert the data strobe signal DQS swinging at the CML level to swing at a CMOS level. The CMOS driver 122 may output a data strobe signal DQS which swings at the CMOS level.

According to some implementations, the CML driver 110 and the power insensitive unit 120 may be driven by an external supply power PWR having an external supply power voltage VCCQ. However, delay values of the CML-CMOS converter 121 and the CMOS driver 122 may sensitively change according to changes in the external supply power voltage VCCQ. Accordingly, the bias generator 130 may generate a bias voltage VBIAS based on a change in the external supply power voltage VCCQ. The power insensitive unit 120 may apply the bias voltage VBIAS to variable sources of the CML-CMOS converter 121 and the CMOS driver 122. Accordingly, the power insensitive unit 120 may constantly maintain a delay of the data strobe signal DQS regardless of changes in the external supply power voltage VCCQ.

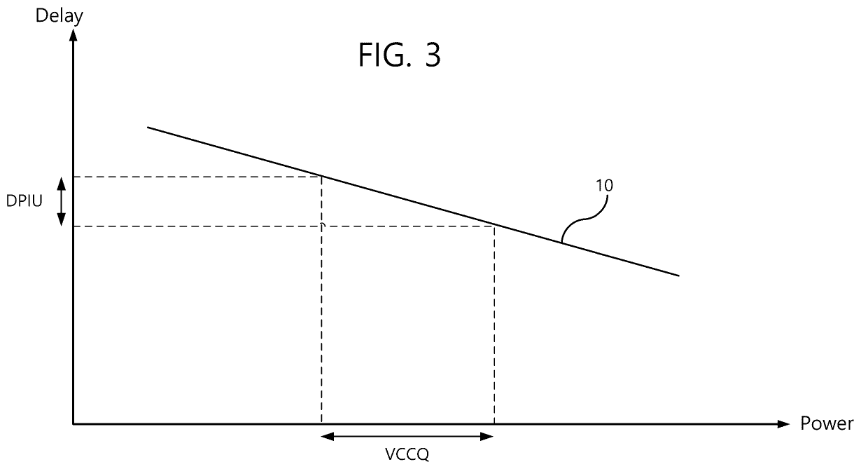

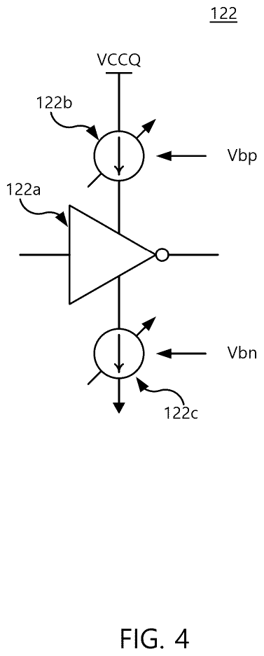

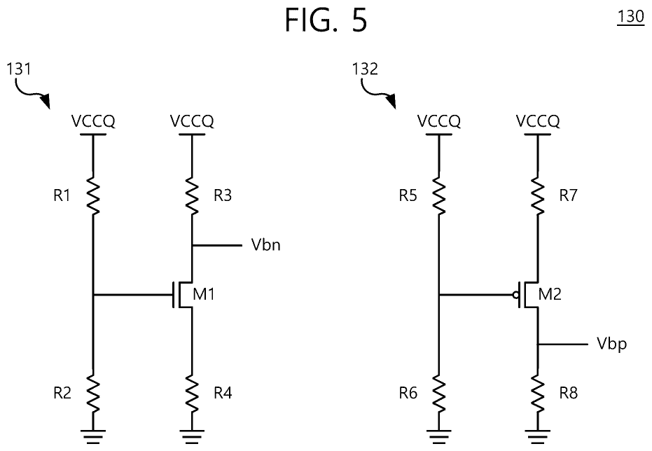

FIG. 3 is a graph illustrating an example of a change in delay value of the power insensitive unit of FIG. 2 according to external power variations according to some implementations. FIG. 4 is a diagram illustrating an example of one inverter included in the CMOS driver of FIG. 2 according to some implementations. FIG. 5 is a diagram illustrating an example of the bias generator of FIG. 2 according to some implementation. In FIGS. 2 and 3, in a graph 10, a delay value DPIU of the power insensitive unit 120 may decrease as the external supply power voltage VCCQ of the external supply power PWR increases.

According to some implementations, the delay value DPIU of the power insensitive unit 120 may change according to a change in the external supply power voltage VCCQ. Accordingly, referring to FIG. 4, an inverter 122a included in the CMOS driver 122 of FIG. 2 may be driven by variable sources 122b and 122c. The variable sources 122b and 122c may be controlled based on bias voltages Vbp and Vbn which change according to the external supply power voltage VCCQ.

As an example, when the external supply power voltage VCCQ increases, the first bias voltage Vbn may decrease and the second bias voltage Vbp may increase. When the external supply power voltage VCCQ decreases, the first bias voltage Von may increase and the second bias voltage Vbp may decrease.

According to some implementations, the bias generator 130 may generate the first bias voltage Vbn and the second bias voltage Vbp. In FIG. 5, the bias generator 130 may include a first bias generation circuit 131 and/or a second bias generation circuit 132. The first bias generation circuit 131 may output the first bias voltage Vbn according to a change in the external supply power voltage VCCQ. The second bias generation circuit 132 may output the second bias voltage Vbp according to the change in the external supply power voltage VCCQ.

As an example, the first bias generation circuit 131 may include a first transistor M1 and a plurality of resistors R1, R2, R3 and R4. The first resistor R1 may be connected between the external supply power voltage VCCQ and a gate of the first transistor M1. The second resistor R2 may be connected between the gate of the first transistor M1 and a ground terminal. The third resistor R3 may be connected between the external supply power voltage VCCQ and a source of the first transistor M1. The fourth resistor R4 may be connected between a drain of the first transistor M1 and the ground terminal. The first transistor M1 may be an N-type transistor. The first bias voltage Vbn may be output through the source of the first transistor M1.

As an example, the second bias generation circuit 132 may include a second transistor M2 and a plurality of resistors R5, R6, R7 and R8. The fifth resistor R5 may be connected between the external supply power voltage VCCQ and a gate of the second transistor M2. The sixth resistor R6 may be connected between the gate of the second transistor M2 and the ground terminal. The seventh resistor R7 may be connected between the external supply power voltage VCCQ and a drain of the second transistor M2. The eighth resistor R8 may be connected between a source of the second transistor M2 and the ground terminal. The second transistor M2 may be a P-type transistor. The second bias voltage Vbp may be output through the source of the second transistor M2.

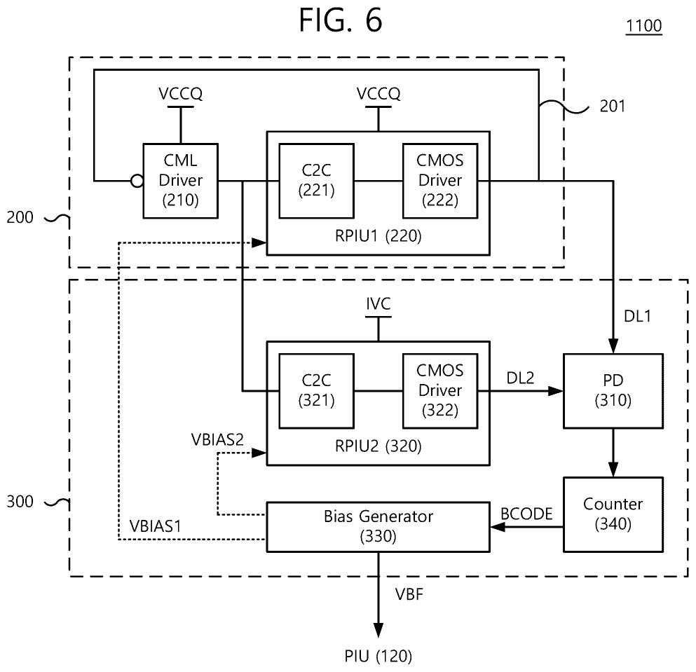

FIG. 6 is a block diagram illustrating examples of a DQS oscillator and a delay calibration circuit according to some implementations. In FIGS. 2 and 6, the memory device 1100 may further include a DQS oscillator 200 and/or a delay calibration circuit 300.

According to some implementations, the DQS oscillator 200 may correct a delay of the clock distribution circuit 100 of FIG. 2 according to environmental changes. For example, the delay of the clock distribution circuit 100 may change according to a change in temperature of the memory device 1100. When a DQS oscillation command is received from the memory controller 1200 of FIG. 1, the DQS oscillator 200 may perform a DQS oscillation.

According to some implementations, the DQS oscillator 200 may be configured as a replica circuit of the clock distribution circuit 100. For example, the DQS oscillator 200 may include a CML driver 210 and a first replica power insensitive unit 220. The CML driver 210 may be configured identically to the CML driver 110 of FIG. 2. The first replica power insensitive unit 220 may be configured in the same manner as the power insensitive unit 120 of FIG. 2. The first replica power insensitive unit 220 may include a C2C converter 221 and a CMOS driver 222. Additionally, the DQS oscillator 200 may include a feedback loop 201 which inverts the first delay signal DL1 output from the CMOS driver 222 and inputs the inverted signal of the first delay signal DL1 to the CML driver 210.

According to some implementations, the delay calibration circuit 300 may utilize the DQS oscillator 200 to generate a final bias voltage VBF to be used in the power insensitive unit 120 of FIG. 2. For example, the delay calibration circuit 300 may include a phase detector 310, a second replica power insensitive unit 320, a bias generator 330 and/or a counter 340. The second replica power insensitive unit 320 may be configured in the same way as the first replica power insensitive unit 220. The second replica power insensitive unit 320 may include a C2C converter 321 and a CMOS driver 322.

According to some implementations, the second replica power insensitive unit 320 may be driven with an internal power voltage IVC which is unrelated to changes in the external supply power voltage VCCQ of the external supply power PWR. For example, the control logic 1160 of FIG. 2 may include an LDO circuit which generates the internal power supply voltage IVC. The internal power supply voltage IVC may be set larger or smaller than the external supply power voltage VCCQ.

According to some implementations, the phase detector 310 may detect a phase difference between the first delay signal DL1 and a second delay signal DL2. For example, the first replica power insensitive unit 220 may output the first delay signal DL1 based on the external supply power voltage VCCQ. The DQS oscillator 200 may generate the first delay signal DL1 while performing a DQS oscillation. The second replica power insensitive unit 320 may output the second delay signal DL2 based on the internal power supply voltage IVC.

According to some implementations, the counter 340 may generate a bias code BCODE based on the phase difference between the first delay signal DL1 and the second delay signal DL2. For example, counter 340 may store a reference code. The counter 340 may increase or decrease the reference code by a specified bit (for example, 1 bit) based on the output of the phase detector 310. When there is no phase difference between the first delay signal DL1 and the second delay signal DL2 (or when the first delay signal DL1 and the second delay signal DL2 are the same), the counter 340 may not change the bias code BCODE.

According to some implementations, the bias generator 330 may determine whether to repeat the delay calibrating operation. For example, the bias generator 330 may store the bias code BCODE. When a bias code different from a previous bias code is received, the bias generator 330 may send a first bias voltage VBIAS1 corresponding to the external supply power voltage VCCQ based on the changed bias code to the first replica power insensitive unit 220. Additionally, the bias generator 330 may transmit a second bias voltage VBIAS2 corresponding to the internal power voltage IVC to the second replica power insensitive unit 320 based on a changed bias code. Then, the first replica power insensitive unit 220 and the second replica power insensitive unit 320 may perform the delay calibrating operation again.

As an example, when the same bias code as a previous bias code is received, the bias generator 330 may store the final bias voltage VBF corresponding to a last received bias code. As another example, when a bias code within a specified difference from a previous bias code is received, the bias generator 330 may store the final bias voltage VBF corresponding to a last received bias code. As another example, when bias codes received during a specified time repeatedly increase and decrease, the bias generator 330 may store the final bias voltage VBF corresponding to one of the bias codes received during the specified time.

According to some implementations, the bias generator 330 may transfer the final bias voltage VBF to the power insensitive unit 120 of FIG. 2. For example, when the final bias voltage VBF is determined, the bias generator 330 may end the delay calibrating operation and transmit the final bias voltage VBF to the main power insensitive unit 120 of FIG. 2.

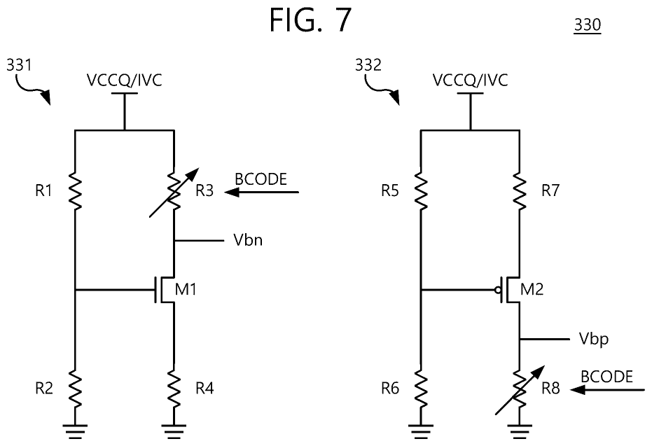

FIG. 7 is a diagram illustrating an example of the bias generator of FIG. 6 according to some implementations. In FIG. 7, the bias generator 330 may include a first bias generation circuit 331 and a second bias generation circuit 332. The first bias generation circuit 331 and the second bias generation circuit 332 may include a similar configuration to the first bias generation circuit 131 and the second bias generation circuit 132 of FIG. 5.

According to some implementations, the first bias generation circuit 331 may include at least one variable resistor (for example, a third resistor R3). The variable resistor may be changed based on the bias code BCODE. The second bias generation circuit 332 may include at least one variable resistor (for example, an eighth resistor R8). The variable resistor may be changed based on the bias code BCODE.

According to some implementations, the first bias generation circuit 331 and the second bias generation circuit 332 may operate based on the external supply power voltage VCCQ or the internal power supply voltage IVC. When generating the first bias voltage VBIAS1 transmitted to the first replica power insensitive unit 220, the first bias generation circuit 331 and the second bias generation circuit 332 may operate based on the external supply power voltage VCCQ. When generating the second bias voltage VBIAS2 transmitted to the second replica power insensitive unit 320, the first bias generation circuit 331 and the second bias generation circuit 332 may operate based on the internal power supply voltage IVC.

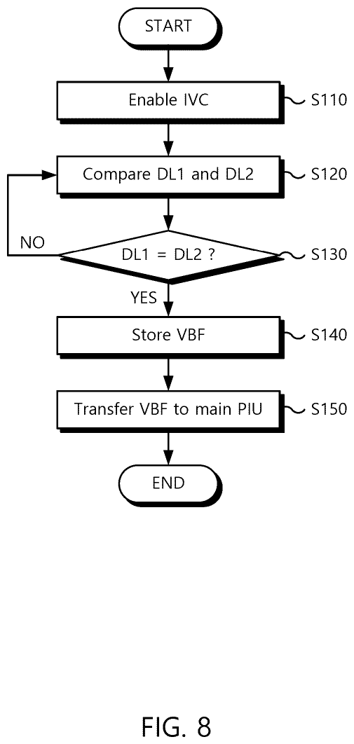

FIG. 8 is a flowchart illustrating an example of a delay calibrating operation performed through the DQS oscillator and the delay calibration circuit of FIG. 6 according to some implementations. In FIGS. 6 and 8, the memory device 1100 may obtain the final bias voltage VBF to be used in the main power insensitive unit 120 of FIG. 2 through the DQS oscillator 200 and the delay calibration circuit 300. Accordingly, the clock distribution circuit 100 of the memory device 1100 may have a constant delay regardless of a voltage change of the external supply power PWR.

According to some implementations, in operation S110, the memory device 1100 may apply the internal power voltage IVC to the delay calibration circuit 300. For example, when a specified command (for example, a DQS oscillation command) is received from the memory controller 1200, the internal power voltage IVC may be supplied to the second replica power insensitive unit 320 of the delay calibration circuit 300. The internal power supply voltage IVC may be set larger or smaller than the external supply power voltage VCCQ.

According to some implementations, in operation S120, the memory device 1100 may compare a phase difference between the first delay signal DL1 and the second delay signal DL2. For example, the first replica power insensitive unit 220 may output the first delay signal DL1 based on the external supply power voltage VCCQ. The second replica power insensitive unit 320 may output the second delay signal DL2 based on the internal power supply voltage IVC.

According to some implementations, in operation S130, the memory device 1100 may check whether a phase of the first delay signal DL1 and a phase of the second delay signal DL2 are the same. For example, the phase detector 310 may detect a phase difference between the first delay signal DL1 and the second delay signal DL2. The counter 340 may generate the bias code BCODE based on the phase difference between the first delay signal DL1 and the second delay signal DL2. When the first delay signal DL1 and the second delay signal DL2 are different, the memory device 1100 may perform operation S120 again. When the first delay signal DL1 and the second delay signal DL2 are the same, the memory device 1100 may perform operation S140.

According to some implementations, in operation S140, the memory device 1100 may store a final bias voltage VBF. For example, when the same bias code as a previous bias code is received, the bias generator 330 may store the final bias voltage VBF corresponding to the last received bias code.

According to some implementations, in operation S150, the memory device 1100 may transmit the final bias voltage VBF to the main power insensitive unit 120 of FIG. 2. For example, when the final bias voltage VBF is determined, the bias generator 330 may end the delay calibrating operation and transmit the final bias voltage VBF to the main power insensitive unit 120 of FIG. 2.

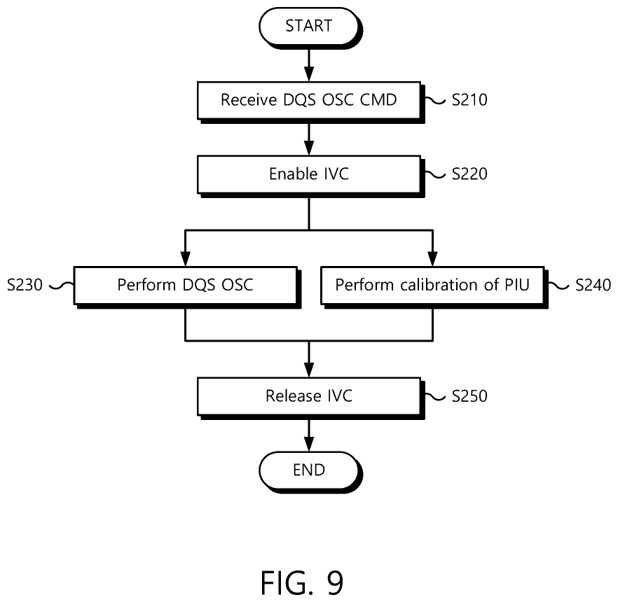

FIG. 9 is a flowchart illustrating an example of a delay calibrating operation performed together with a DQS oscillation of the memory device of FIG. 2 according to some implementations. In FIGS. 2, 6 and 9, the memory device 1100 may perform a delay calibrating operation together with a DQS oscillation or simultaneously while the DQS oscillation is performed. Accordingly, the delay calibrating operation may be hidden in the basic DQS oscillation, and an operating speed of the memory device 1100 may be maintained.

According to some implementations, in operation S210, the memory device 1100 may receive a DQS oscillation command (DQS OSC CMD) from the memory controller 1200 of FIG. 2. For example, when the DQS oscillation command (DQS OSC CMD) is received, the control logic 1160 of FIG. 2 may prepare a delay calibrating operation along with the DQS oscillation.

According to some implementations, in operation S220, the memory device 1100 may apply the internal power voltage IVC to the delay calibration circuit 300. For example, the control logic 1160 may generate the internal power supply voltage IVC. The internal power voltage IVC may be supplied to the second replica power insensitive unit 320 of the delay calibration circuit 300. The internal power supply voltage IVC may be set larger or smaller than the external supply power voltage VCCQ.

According to some implementations, in operation S230, the memory device 1100 may perform the DQS oscillation (DQS OSC) in response to the DQS oscillation command (DQS OSC CMD). For example, the control logic 1160 may perform the DQS oscillation (DQS OSC) through the DQS oscillator 200.

According to some implementations, in operation S240, while the DQS oscillation (DQS OSC) is being performed, the memory device 1100 may also perform the delay calibrating operation. For example, the DQS oscillator 200 and the delay calibration circuit 300 may perform the delay calibrating operation of FIG. 8.

According to some implementations, in operation S250, the memory device 1100 may release a supply of the internal power voltage IVC from the delay calibration circuit 300. For example, when the DQS oscillation (DQS OSC) ends, the delay calibrating operation may also end. As another example, at an end of the DQS oscillation (DQS OSC) or the delay calibrating operation which ends later, the internal power supply voltage IVC may be cut off.

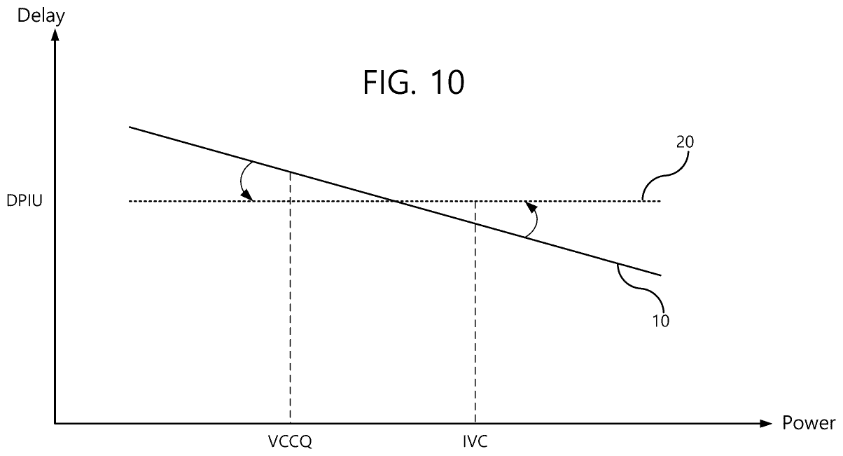

FIG. 10 is a graph illustrating an example of an effect of the delay calibrating operation of FIG. 8 according to some implementations. In FIG. 10, a delay value DPIU of the power insensitive unit 120 may be changed from a first graph 10 to a second graph 20. By the delay calibrating operation of FIG. 8, delay values of the power insensitive unit 120 at the external supply power voltage VCCQ and the internal power supply voltage IVC may be measured on the first graph 10. The delay calibrating operation may be performed repeatedly in a direction of reducing a difference between the delay values. Accordingly, the delay value DPIU of the power insensitive unit 120 may be finally changed to follow the second graph 20. The delay value DPIU of the power insensitive unit 120 may constantly be maintained regardless of a change in the external supply power voltage VCCQ of the external supply power PWR.

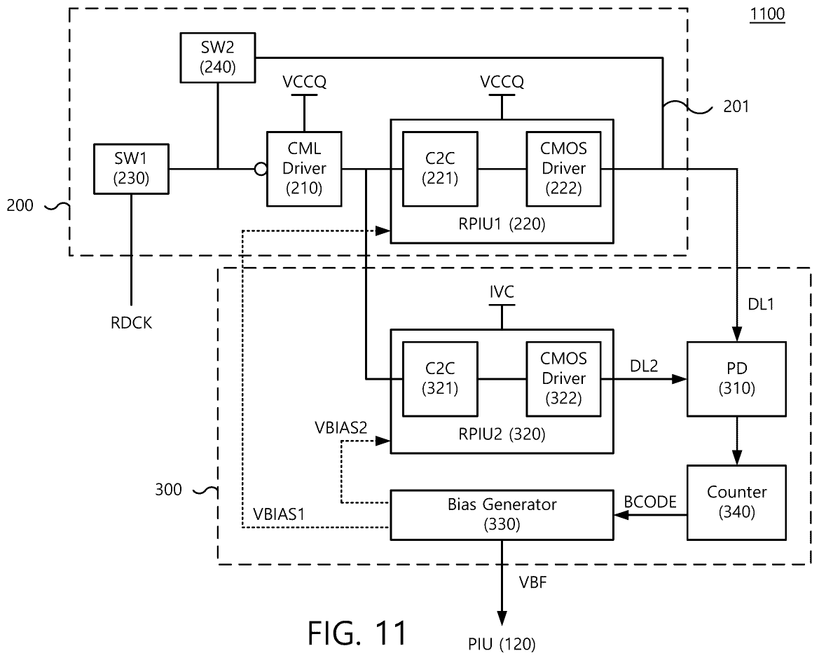

FIG. 11 is a block diagram illustrating examples of a DQS oscillator and a delay calibration circuit according to some implementations. In FIGS. 2 and 11, the memory device 1100 may further include a DQS oscillator 200 and/or a delay calibration circuit 300.

According to some implementations, the DQS oscillator 200 may correct a delay of the clock distribution circuit 100 of FIG. 2 according to environmental changes. For example, the delay of the clock distribution circuit 100 may change according to a change in temperature of the memory device 1100. When a DQS oscillation command is received from the memory controller 1200 of FIG. 1, the DQS oscillator 200 may perform a DQS oscillation.

According to some implementations, the DQS oscillator 200 may be configured as a replica circuit of the clock distribution circuit 100. For example, the DQS oscillator 200 may include a CML driver 210 and a first replica power insensitive unit 220. The CML driver 210 may be configured identically to the CML driver 110 of FIG. 2. The first replica power insensitive unit 220 may be configured in the same manner as the power insensitive unit 120 of FIG. 2. The first replica power insensitive unit 220 may include a C2C converter 221 and a CMOS driver 222. Additionally, the DQS oscillator 200 may include a feedback loop 201 which inverts the first delay signal DL1 output from the CMOS driver 222 and inputs an inverted signal of the first delay signal DL1 to the CML driver 210.

According to some implementations, the DQS oscillator 200 may be used as part of the delay calibration circuit 300 when receiving a duty cycle correction command from the memory controller 1200 of FIG. 1. For example, the DQS oscillator 200 may further include a first switch 230 and a second switch 240. When the duty cycle correction command is received from the memory controller 1200 of FIG. 1, the first switch 230 may be turned on and the second switch 240 may be turned off. Accordingly, a read clock RDCK received from the memory controller 1200 may be input to the CML driver 210, and the feedback loop 201 may be cut off.

According to some implementations, the delay calibration circuit 300 may utilize the DQS oscillator 200 to generate a final bias voltage VBF to be used in the power insensitive unit 120 of FIG. 2. For example, the delay calibration circuit 300 may include a phase detector 310, a second replica power insensitive unit 320, a bias generator 330 and/or a counter 340. The second replica power insensitive unit 320 may be configured in the same way as the first replica power insensitive unit 220. The second replica power insensitive unit 320 may include a C2C converter 321 and a CMOS driver 322.

According to some implementations, the second replica power insensitive unit 320 may be driven with an internal power voltage IVC which is unrelated to changes in the external supply power voltage VCCQ of the external supply power PWR. For example, the control logic 1160 of FIG. 2 may include an LDO circuit which generates the internal power supply voltage IVC. The internal power supply voltage IVC may be set larger or smaller than the external supply power voltage VCCQ.

According to some implementations, the phase detector 310 may detect a phase difference between the first delay signal DL1 and the second delay signal DL2. For example, the first replica power insensitive unit 220 may output the first delay signal DL1 based on the external supply power voltage VCCQ. The DQS oscillator 200 may generate the first delay signal DL1 while performing a duty cycle correction. The second replica power insensitive unit 320 may output the second delay signal DL2 based on the internal power supply voltage IVC.

According to some implementations, the counter 340 may generate a bias code BCODE based on a phase difference between the first delay signal DL1 and the second delay signal DL2. For example, the counter 340 may store a reference code. The counter 340 may increase or decrease the reference code by a specified bit (for example, 1 bit) based on an output of the phase detector 310. When there is no phase difference between the first delay signal DL1 and the second delay signal DL2 (or when the first delay signal DL1 and the second delay signal DL2 are the same), the counter 340 may not change the bias code BCODE.

According to some implementations, the bias generator 330 may determine whether to repeat the delay calibrating operation. For example, bias generator 330 may store the bias code BCODE. When a bias code different from the previous bias code is received, the bias generator 330 may send a first bias voltage VBIAS1 corresponding to the external supply power voltage VCCQ based on a changed bias code to the first replica power insensitive unit 220. Additionally, the bias generator 330 may transmit a second bias voltage VBIAS2 corresponding to the internal power voltage IVC to the second replica power insensitive unit 320 based on the changed bias code. Then, the first replica power insensitive unit 220 and the second replica power insensitive unit 320 may perform the delay calibrating operation again.

As an example, when the same bias code as the previous bias code is received, the bias generator 330 may store the final bias voltage VBF corresponding to the last received bias code. As another example, when a bias code within a specified difference from the previous bias code is received, the bias generator 330 may store the final bias voltage VBF corresponding to the last received bias code. As another example, when bias codes received during a specified time repeatedly increase and decrease, the bias generator 330 may store the final bias voltage VBF corresponding to one of the bias codes received during the specified time.

According to some implementations, the bias generator 330 may transfer the final bias voltage VBF to the power insensitive unit 120 of FIG. 2. For example, when the final bias voltage VBF is determined, the bias generator 330 may end the delay calibrating operation and transmit the final bias voltage VBF to the main power insensitive unit 120 of FIG. 2.

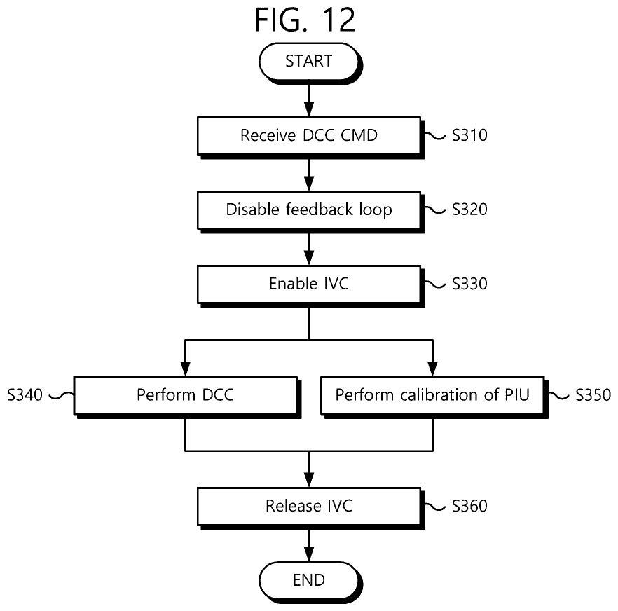

FIG. 12 is a flowchart illustrating an example of a delay calibrating operation performed simultaneously with a duty cycle correction of the memory device of FIG. 2 according to some implementations. In FIGS. 2, 11 and 12, the memory device 1100 may perform a delay calibrating operation simultaneously or simultaneously while a duty cycle correction (DCC) is performed. Accordingly, a delay calibrating operation may be hidden in the basic duty cycle correction (DCC), and the operating speed of the memory device 1100 may be maintained.

In operation S310, the memory device 1100 may receive a DCC command (DCC CMD) from the memory controller 1200 of FIG. 2. For example, when the DCC command (DCC CMD) is received, the control logic 1160 of FIG. 2 may prepare the delay calibrating operation along with the duty cycle correction (DCC).

In operation S320, the memory device 1100 may block the feedback loop 201 of the DQS oscillator 200. For example, the DQS oscillator 200 may include a first switch 230 and a second switch 240. When the DCC command (DCC CMD) is received, the first switch 230 may be turned on and the second switch 240 may be turned off. Accordingly, a read clock RDCK received from the memory controller 1200 may be input to the CML driver 210, and the feedback loop 201 may be cut off.

In operation S330, the memory device 1100 may apply the internal power voltage IVC to the delay calibration circuit 300. For example, the control logic 1160 may generate the internal power supply voltage IVC. The internal power voltage IVC may be supplied to the second replica power insensitive unit 320 of the delay calibration circuit 300. The internal power supply voltage IVC may be set larger or smaller than the external supply power voltage VCCQ.

In operation S340, the memory device 1100 may perform the duty cycle correction (DCC) in response to the DCC command (DCC CMD). For example, control logic 1160 may perform the duty cycle correction (DCC).

In operation S350, while the duty cycle correction (DCC) is being performed, the memory device 1100 may also perform the delay calibrating operation. For example, the DQS oscillator 200 and the delay calibration circuit 300 may perform the delay calibrating operation of FIG. 8.

In operation S360, the memory device 1100 may release a supply of the internal power voltage IVC from the delay calibration circuit 300. For example, when the duty cycle correction (DCC) ends, the delay calibrating operation may also end. As another example, at an end of the duty cycle correction (DCC) or the delay calibrating operation which ends later, the internal power supply voltage IVC may be cut off.

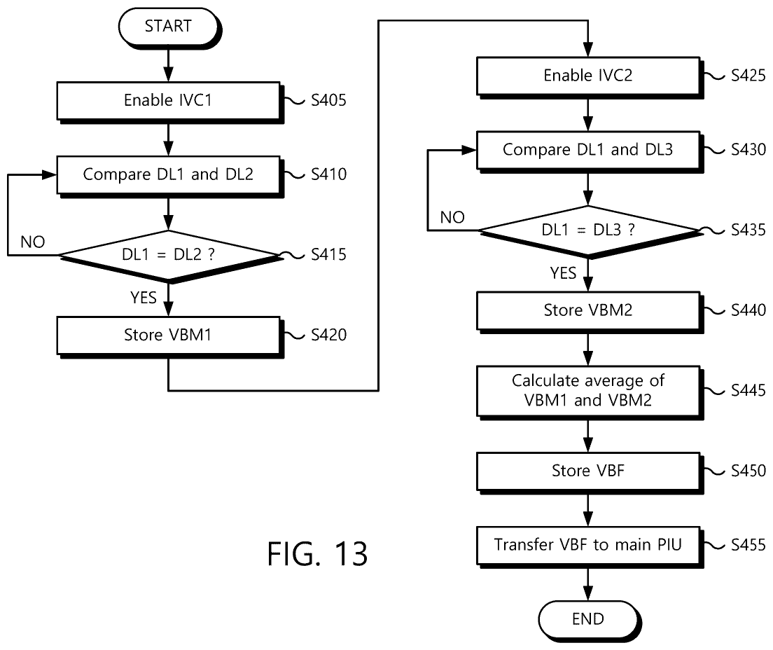

FIG. 13 is a flowchart illustrating an example of a delay calibrating operation performed through the DQS oscillator and the delay calibration circuit of FIG. 6 according to some implementations. Referring to FIGS. 6 and 13, the memory device 1100 may obtain the final bias voltage VBF to be used in the main power insensitive unit 120 of FIG. 2 through the DQS oscillator 200 and the delay calibration circuit 300. Accordingly, the clock distribution circuit 100 of the memory device 1100 may have a constant delay regardless of a voltage change of the external supply power PWR.

In operation S405, the memory device 1100 may apply a first internal power voltage IVC1 to the delay calibration circuit 300. For example, when a specified command (for example, a DQS oscillation command or a DCC command) is received from the memory controller 1200, the first internal power supply voltage IVC1 may be supplied to the second replica power insensitive unit 320 of the delay calibration circuit 300. As an example, the first internal power voltage IVC1 may be set to be greater than the external supply power voltage VCCQ.

In operation S410, the memory device 1100 may compare a phase difference between a first delay signal DL1 and a second delay signal DL2. For example, the first replica power insensitive unit 220 may output the first delay signal DL1 based on the external supply power voltage VCCQ. The second replica power insensitive unit 320 may output the second delay signal DL2 based on the first internal power supply voltage IVC1.

In operation S415, the memory device 1100 may check whether a phase of the first delay signal DL1 and a phase of the second delay signal DL2 are the same. For example, the phase detector 310 may detect the phase difference between the first delay signal DL1 and the second delay signal DL2. The counter 340 may generate a bias code BCODE based on the phase difference between the first delay signal DL1 and the second delay signal DL2. When the first delay signal DL1 and the second delay signal DL2 are different, the memory device 1100 may perform operation S410 again. When the first delay signal DL1 and the second delay signal DL2 are the same, the memory device 1100 may perform operation S420.

In operation S420, the memory device 1100 may store a first intermediate bias voltage VBM1. For example, when the same bias code as a previous bias code is received, the bias generator 330 may store the first intermediate bias voltage VBM1 corresponding to the last received bias code. As another example, when a bias code within a specified difference from the previous bias code is received, the bias generator 330 may store the first intermediate bias voltage VBM1 corresponding to the last received bias code. As another example, when bias codes received during a specified time repeat increasing and decreasing, the bias generator 330 may store the first intermediate bias voltage VBM1 corresponding to one of the bias codes received during the specified time.

In operation S425, the memory device 1100 may apply a second internal power voltage IVC2 to the delay calibration circuit 300. For example, the second internal power voltage IVC2 may be supplied to the second replica power insensitive unit 320 of the delay calibration circuit 300. As an example, the second internal power voltage IVC2 may be set to be smaller than the external supply power voltage VCCQ.

In operation S430, the memory device 1100 may compare a phase difference between the first delay signal DL1 and a third delay signal DL3. For example, the first replica power insensitive unit 220 may output the first delay signal DL1 based on the external supply power voltage VCCQ. The second replica power insensitive unit 320 may output the third delay signal DL3 based on the second internal power supply voltage IVC2.

In operation S435, the memory device 1100 may check whether the phase of the first delay signal DL1 and the phase of the third delay signal DL3 are the same. For example, the phase detector 310 may detect the phase difference between the first delay signal DL1 and the third delay signal DL3. The counter 340 may generate a bias code BCODE based on the phase difference between the first delay signal DL1 and the third delay signal DL3. When the first delay signal DL1 and the third delay signal DL3 are different, the memory device 1100 may perform operation S430 again. When the first delay signal DL1 and the third delay signal DL3 are the same, the memory device 1100 may perform operation S440.

In operation S440, the memory device 1100 may store a second intermediate bias voltage VBM2. For example, when the same bias code as a previous bias code is received, the bias generator 330 may store the second intermediate bias voltage VBM2 corresponding to the last received bias code. As another example, when a bias code within a specified difference from a previous bias code is received, the bias generator 330 may store the second intermediate bias voltage VBM2 corresponding to the last received bias code. As another example, when bias codes received during a specified time repeat increasing and decreasing, the bias generator 330 may store the second intermediate bias voltage VBM2 corresponding to one of the bias codes received during the specified time.

In operation S445, the memory device 1100 may calculate an average of the first intermediate bias voltage VBM1 and the second intermediate bias voltage VBM2. For example, the bias generator 330 may determine the average value of the first intermediate bias voltage VBM1 and the second intermediate bias voltage VBM2 as the final bias voltage VBF.

In operation S450, the memory device 1100 may store the final bias voltage VBF. For example, the bias generator 330 may store the final bias voltage VBF.

In operation S455, the memory device 1100 may transmit the final bias voltage VBF to the main power insensitive unit 120 of FIG. 2. For example, when the final bias voltage VBF is determined, the bias generator 330 may end the delay calibrating operation and transmit the final bias voltage VBF to the main power insensitive unit 120 of FIG. 2.

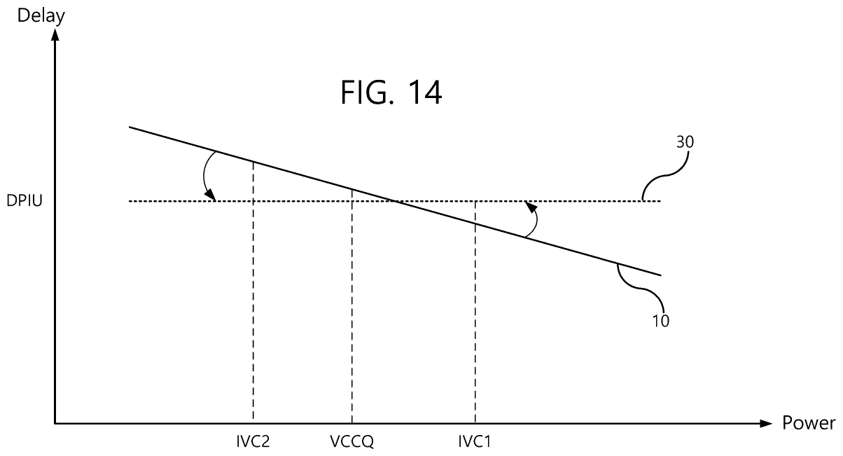

FIG. 14 is a graph illustrating an example of an effect of the delay calibrating operation of FIG. 13 according to some implementations. In FIG. 14, a delay value DPIU of the power insensitive unit 120 may be changed from a first graph 10 to a third graph 30. By the delay calibrating operation of FIG. 13, delay values of the power insensitive unit 120 at the external supply power voltage VCCQ and the internal power supply voltages IVC1 and IVC2 may be measured on the first graph 10, and the delay calibrating operation may be performed repeatedly in a direction of reducing difference between the delay values. Accordingly, the delay value DPIU of the power insensitive unit 120 may be finally changed to follow the third graph 30. The delay value DPIU of the power insensitive unit 120 may be constantly maintained regardless of the change in the external supply power voltage VCCQ of the external supply power PWR.

According to the present disclosure, it may be possible to constantly maintain a delay of a data strobe signal regardless of a change in voltage of external supply power received from the memory controller.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array including a plurality of memory cells;
an input/output circuit configured to transmit data read from the memory cell array to a memory controller;
control logic circuitry configured to generate a data strobe signal corresponding to the data transmitted to the memory controller;
a clock distribution circuit including a main power insensitive circuit, the main power insensitive circuit having a delay value and configured to be driven by an external supply power voltage supplied from the memory controller, the clock distribution circuit being configured to transmit the data strobe signal passing through the main power insensitive circuit to the input/output circuit;
a data strobe signal oscillator configured to be driven by the external supply power voltage, the data strobe signal oscillator including a first replica power insensitive circuit configured to have the delay value; and
a delay calibration circuit configured to generate a bias voltage in a direction in which a phase difference between a first delay signal and a second delay signal decreases based upon a comparison of the first delay signal output from the data strobe signal oscillator and the second delay signal output from a second replica power insensitive circuit, the second replica power insensitive circuit being configured to have the delay value and being driven by an internal power voltage different from the external supply power voltage,
wherein the clock distribution circuit is configured to adjust the delay value of the main power insensitive circuit based on the bias voltage.

2. The memory device of claim 1, wherein the delay calibration circuit comprises:
a phase detector configured to detect the phase difference between the first delay signal and the second delay signal;
a counter configured to increase or decrease a reference code based on an output of the phase detector and configured to output a bias code; and
a bias generator configured to generate the bias voltage based on the bias code.

3. The memory device of claim 2,
wherein the bias generator is configured to, based on the bias code being changed, store a first bias voltage corresponding to the external supply power voltage and a second bias voltage corresponding to the internal power voltage,
wherein the first replica power insensitive circuit is configured to output the first delay signal again based on the first bias voltage,
wherein the second replica power insensitive circuit is configured to output the second delay signal again based on the second bias voltage.

4. The memory device of claim 2, wherein the bias generator is configured to, based on a bias code identical to a previous bias code being received from the counter, store a bias voltage corresponding to the previous bias code as a final bias voltage.

5. The memory device of claim 4,
wherein the bias generator is configured to transmit the final bias voltage to the main power insensitive circuit,
wherein the main power insensitive circuit is configured to change the delay value based on the final bias voltage.

6. The memory device of claim 1, wherein the control logic circuitry is configured to control the data strobe signal oscillator to perform a data strobe signal oscillation operation when receiving a data strobe signal oscillation command from the memory controller, and supply the internal power voltage to the second replica power insensitive circuit while the data strobe signal oscillation operation is performed.

7. The memory device of claim 1, wherein the data strobe signal oscillator comprises:
a current mode logic driver configured to supply a signal to the first replica power insensitive circuit;
a feedback loop configured to invert an output signal of the first replica power insensitive circuit and supply an inverted signal of the output signal to the current mode logic driver;
a first switch configured to turn on or off a signal line input to the current mode logic driver; and
a second switch configured to connect or block the feedback loop.

8. The memory device of claim 7, wherein the control logic circuitry is configured to, based on a duty cycle correction command being received from the memory controller, turn on the first switch, turn off the second switch, and supply a read clock received from the memory controller to the current mode logic driver through the first switch.

9. The memory device of claim 8, wherein the control logic circuitry is configured to control the clock distribution circuit to perform a duty cycle correction and supply the internal power voltage to the second replica power insensitive circuit while the duty cycle correction is performed.

10. A delay calibration method of a memory device, the method comprising:
providing the memory device including:
control logic circuitry configured to generate a data strobe signal,
a main power insensitive circuit configured to be driven by an external supply power voltage and transmit the data strobe signal according to a delay value,
a first replica power insensitive circuit configured to be driven by the external supply power voltage and having the delay value, and
a second replica power insensitive circuit configured to be driven by an internal power supply voltage generated by the control logic circuit, the second replica power insensitive circuit having the delay value,
receiving a data strobe signal oscillation command from a memory controller;
in response to receiving the data strobe signal oscillation command, providing the internal power supply voltage to the second replica power insensitive circuit;
in response to the data strobe signal oscillation command, performing a data strobe signal oscillation operation;
based on the data strobe signal oscillation operation being performed, performing a delay calibrating operation by the first replica power insensitive circuit and the second replica power insensitive circuit; and
based on the data strobe signal oscillation operation ending, blocking supply of the internal power supply voltage to the second replica power insensitive circuit.

11. The method of claim 10, wherein performing the delay calibrating operation comprises:
comparing a phase difference between a first delay signal output from the first replica power insensitive circuit and a second delay signal output from the second replica power insensitive circuit;
generating, based on the phase difference between the first delay signal and the second delay signal, a bias code configured to increase or decrease a reference code;
generating, based on the bias code, a first bias voltage corresponding to the external supply power voltage and a second bias voltage corresponding to the internal power supply voltage; and
applying the first bias voltage to the first replica power insensitive circuit and applying the second bias voltage to the second replica power insensitive circuit to repeatedly compare the first delay signal and the second delay signal.

12. The method of claim 11, wherein comparing the phase difference comprises:
storing a current bias voltage as a final bias voltage when the first delay signal and the second delay signal have a same phase; and
applying the final bias voltage to the main power insensitive circuit.

13. The method of claim 10, wherein performing the delay calibrating operation comprises:
providing a first internal power voltage greater than the external supply power voltage to the second replica power insensitive circuit;
comparing a first phase difference between a first delay signal output from the first replica power insensitive circuit and a second delay signal output from the second replica power insensitive circuit;
generating, based on the first phase difference between the first delay signal and the second delay signal, a first bias code configured to increase or decrease a reference code;
generating, based on the first bias code, a first bias voltage corresponding to the external supply power voltage and a second bias voltage corresponding to the internal power supply voltage; and
applying the first bias voltage to the first replica power insensitive circuit and applying the second bias voltage to the second replica power insensitive circuit to repeatedly compare the first delay signal and the second delay signal.

14. The method of claim 13, wherein comparing the first phase difference comprises:
storing a current bias voltage as a first intermediate bias voltage when the first delay signal and the second delay signal have a same phase;
providing a second internal power voltage smaller than the external supply power voltage to the second replica power insensitive circuit;
comparing a second phase difference between the first delay signal and a third delay signal output from the second replica power insensitive circuit;
generating, based on the second phase difference between the first delay signal and the third delay signal, a second bias code configured to increase or decrease the reference code;
generating, based on the second bias code, a third bias voltage corresponding to the external supply power voltage and a fourth bias voltage corresponding to the internal power supply voltage; and
applying the third bias voltage to the first replica power insensitive circuit and applying the fourth bias voltage to the second replica power insensitive circuit to repeatedly compare the first delay signal and the third delay signal.

15. The method of claim 14, wherein comparing the second phase difference comprises:
storing a current bias voltage as a second intermediate bias voltage when the first delay signal and the third delay signal have a same phase;
calculating an average voltage value of the first intermediate bias voltage and the second intermediate bias voltage;
storing the average voltage value as a final bias voltage; and
applying the final bias voltage to the main power insensitive circuit.

16. A delay calibration method of a memory device, the method comprising:
the memory device including control logic circuitry that is configured to generate a data strobe signal, a main power insensitive circuit configured to be driven by an external supply power voltage and to transmit the data strobe signal according to a delay value, and a first replica power insensitive circuit configured to be driven by the external supply power voltage and to have the delay value, and a second replica power insensitive circuit configured to be driven by an internal power supply voltage generated by the control logic circuitry and to have the delay value,
receiving a duty cycle correction command from a memory controller;
in response to receiving the duty cycle correction command, providing the internal power supply voltage to the second replica power insensitive circuit;
in response to the duty cycle correction command, performing a duty cycle correction;
while the duty cycle correction is performed, performing a delay calibrating operation by the first replica power insensitive circuit and the second replica power insensitive circuit; and
when the duty cycle correction ends, blocking supply of the internal power supply voltage to the second replica power insensitive circuit.

17. The method of claim 16,
wherein the memory device further includes:
a first switch configured to control an input signal of the first replica power insensitive circuit; and
a second switch configured to control a feedback loop connected to the first replica power insensitive circuit,
wherein the providing the internal power supply voltage comprises:
turning on the first switch upon receiving the duty cycle correction command; and
turning off the second switch upon receiving the duty cycle correction command.

18. The method of claim 17, wherein the performing the delay calibrating operation comprises:
inputting a read clock received from the memory controller through the first switch to the first replica power insensitive circuit and the second replica power insensitive circuit;
comparing a phase difference between a first delay signal output from the first replica power insensitive circuit and a second delay signal output from the second replica power insensitive circuit;
generating a bias code that increases or decreases a reference code, the bias code being based on the phase difference when the first delay signal and the second delay signal have different phases;
generating, based on the bias code, a first bias voltage corresponding to the external supply power voltage and a second bias voltage corresponding to the internal power supply voltage; and
applying the first bias voltage to the first replica power insensitive circuit and applying the second bias voltage to the second replica power insensitive circuit to repeatedly compare the first delay signal and the second delay signal.

19. The method of claim 18, wherein the comparing the phase difference comprises:
storing a current bias voltage as a final bias voltage when the first delay signal and the second delay signal have a same phase; and
applying the final bias voltage to the main power insensitive circuit.

20. The method of claim 16, wherein the internal power supply voltage is configured to be set to be greater or smaller than the external supply power voltage.
